(19) United States
(12) Patent Application Publication
(10) Pub. No.: US 2024/0292569 A1
(43) Pub. Date: Aug. 29, 2024

(54) COOLING DEVICE

(71) Applicant: EGGTRONIC ENGINEERING SPA, Modena (IT)

(72) Inventors: Igor SPINELLA, Modena (IT); Simone BONETTI, Modena (IT)

(21) Appl. No.: 18/588,234

(22) Filed: Feb. 27, 2024

(30) Foreign Application Priority Data
Feb. 27, 2023 (GB) 2302803.8

(51) Int. Cl. H05K 7/20

(52) U.S. Cl. CPC H05K 7/20409

(57) ABSTRACT

It is disclosed a cooling device comprising: a heat absorbing body, a heat releasing body, and a heat transferring system configured to transfer heat from the heat absorbing body to the heat releasing body, wherein the heat transferring system comprises: a deformable body, a gas within the deformable body, a movable body capable of alternatingly squeezing and releasing a portion of the deformable body, and an electric motor configured to actuate the movable body.

### CROSS-REFERENCE TO RELATED APPLICATIONS

This application claims priority to GB Application No. 2302803.8, filed Feb. 27, 2023, the entire contents of which being fully incorporated herein by reference.

### BACKGROUND OF THE INVENTION

### 1. Field of the Invention

The field of the invention relates to cooling device for transferring heat from a heat absorbing body to a heat releasing body.

A portion of the disclosure of this patent document contains material, which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### 2. Discussion of the Prior Art

Nowadays cooling devices are used in many technical fields, where they are generally configured to draw heat from an object or a space, subsequently cooling this heat and releasing it into the surrounding environment.

Miniaturized cooling devices are sometimes used also in the electronic field to cool electronic components whose temperature must be kept under control. This is crucial for enhancing the electronic components efficiency, as for example but not exclusively the transmission coils of inductive wireless chargers.

At present, these miniaturized cooling devices are usually embodied as solid-state active devices operating based on the Peltier effect.

Each Peltier device comprises two sides. When a DC electric current flows through the device, it brings heat from one side to the other, so that one side gets cooler while the other gets hotter.

The “cool side” may be placed in contact or in proximity with the component to be cooled, in order to absorb heat therefrom, while the “hot” side may be embodied as, or attached to, a heat sink that releases the heat into the environment.

Although these Peltier devices are very simple and can be easily miniaturized, their energy efficiency is generally limited or constrained.

### SUMMARY OF THE INVENTION

An object of the present invention is to provide an alternative cooling device which can advantageously replace conventional Peltier devices and possibly reach high levels of energy efficiency.

These and other objects are achieved by the features of the invention listed in the independent claim. The dependent claims relate to preferred or particularly advantageous aspects of the invention but not strictly necessary to its implementation.

In particular, an embodiment of the invention provides a cooling device comprising:
a heat absorbing body,
a heat releasing body, and
a heat transferring system configured to transfer heat from the heat absorbing body to the heat releasing body,
   wherein the heat transferring system comprises:
a deformable body,
a gas within the deformable body,
a movable body capable of alternatingly squeezing and releasing a portion of the deformable body, and
an electric motor configured to actuate the movable body.

This way, when the movable body or thrusting body squeezes a portion of the deformable body, such as a first portion that is in thermal contact with the heat absorbing body, all the gas contained therein moves in another portion, such as a second portion being in contact with the heat releasing body and undergoing to an adiabatic compression.

This adiabatic compression may cause the gas temperature to increase above the temperature of the heat releasing body.

At this point, while the movable body keeps the second portion of the deformable body squeezed, the hot gas heats the heat releasing body that in turn releases part of this heat to the environment.

In doing this, the gas temperature decreases through an isochoric process.

When the gas temperature is equal or almost equal to the temperature of the heat releasing body, the movable body may release the squeeze, so that the compressed gas is free to flow and to inflate the entire deformable body again, thereby undergoing to an adiabatic expansion.

This adiabatic expansion causes the gas temperature to decrease below the temperature of the heat absorbing body.

At this point, while the first portion of the deformable body is kept inflated, the cold gas cools the heat absorbing body that in turn draws heat from a space or an object to be cooled.

In doing this, the gas temperature increases through an isochoric process.

When the gas temperature is equal or almost equal to the temperature of the heat releasing body, the movable body may squeeze the first portion of the deformable body again and the cycle is repeated.

In view of the above, the cooling device of the present invention is globally able to perform a thermodynamic cycle that transfer heat from the heat absorbing body (cold side of the device), which may be placed in thermal relation with any space or object to be cooled, to the heat releasing body (hot side of the device), which can be simply exposed to the external environment.

The cooling device of the present invention has also the advantages of being able to be manufactured at low cost, to be easily miniaturized and to be quite silent in operation. In addition, the cooling device of the present invention may also achieve high level of energy efficiency.

Further features and advantages of the invention are mentioned in the dependent claims and will be apparent from reading the following description provided by way of example and not limitation.

### BRIEF DESCRIPTION OF THE FIGURES

Aspects of the invention will now be described, by way of example(s), with reference to the following Figures, which each show features of the invention:

FIG. 1 is a bottom view of a cooling device according to an explanatory but not limiting embodiment of the invention, where the electric motor has been omitted for clarity.

FIG. 2 is the section II-II indicated in FIG. 1.

FIG. 3 is a diagram P-V (i.e. Pressure-Volume) showing the thermodynamic cycle performed by the cooling device of FIG. 1.

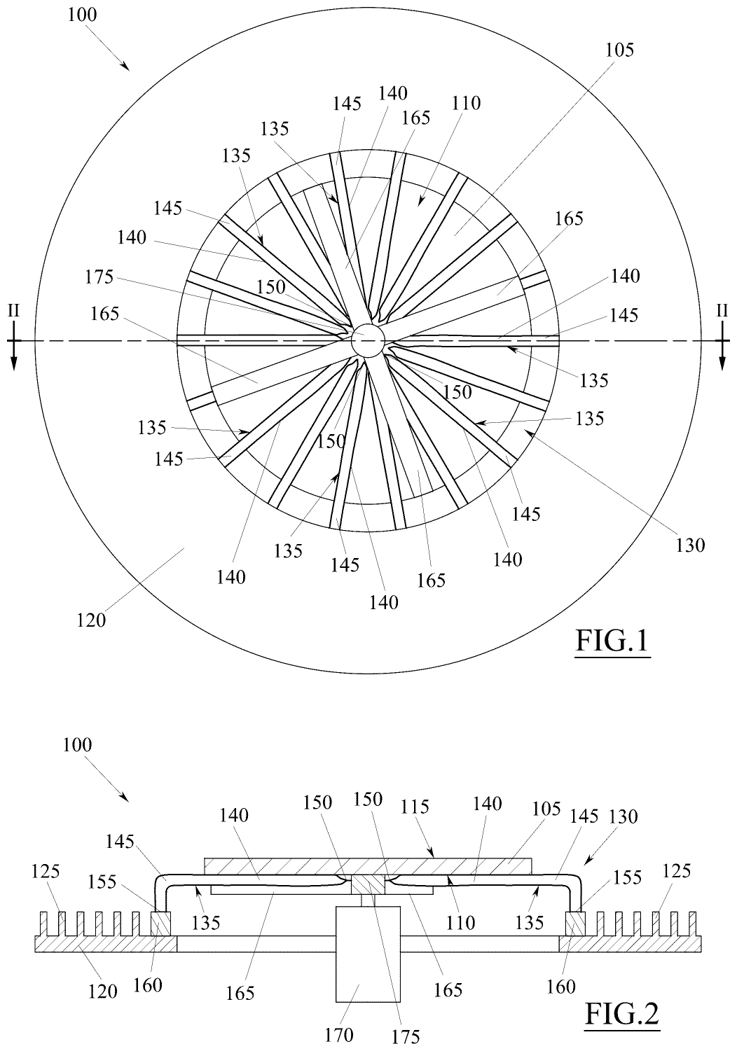

### DETAILED DESCRIPTION

The cooling device 100 comprises a heat absorbing body 105, which can be also referred to as “cold side” of the cooling device 100.

This heat absorbing body 105 may be made of any material capable of absorbing heat, such as metal or any other material having high thermal conductivity and may be shaped so as to comprise at least one flat surface 110.

In particular, the heat absorbing body 105 may be entirely shaped as a flat body, for example as a disk-shaped flat body, having two mutually-opposed flat surface 110 and 115.

The heat absorbing body 105 may be destined to stay in thermal relation with a space or an object to be cooled in order to draw/absorb heat therefrom.

This thermal contact may be achieved on one of the flat surfaces, for example on the flat surface labelled with 115.

The cooling device 100 further comprises a heat releasing body 120, which can be also referred to as “hot side” of the cooling device 100.

This heat releasing body 120 may be made of any material capable of releasing heat, such as metal or any other material having high thermal conductivity.

Also the heat releasing body 120 may be embodied as a flat body, for example as an annular-shaped flat body that lies parallel and concentrically with respect to the heat absorbing body 105.

The heat releasing body 120 may be exposed to the external environment in order to release heat thereto.

In order to enhance the thermal exchange between the external environment and the heat releasing body 120, the latter may be provided with a plurality of thermal dissipative fins 125.

The cooling device 100 then comprises heat transferring system, globally indicated with 130, which are configured to transfer heat from the cold side of the cooling device 100, namely from the heat absorbing body 105, to the hot side of the cooling device 100, namely to the heat releasing body 120.

This heat transferring system 130 comprises a plurality of deformable or compressible hollow bodies 135, each of which comprises a first portion 140 in thermal contact with the heat absorbing body 105, for example with the flat surface 110 thereof, and a second portion 145 in thermal contact with the heat releasing body 120.

It must be observed that two or more objects are meant to be in thermal contact if they are able to exchange heat from one another through thermal conduction.

In the present example, each compressible hollow body 135 may be embodied as a sleeve-shaped body having a first axial end 150, a second axial end 155 and possibly a plurality of lateral branches (not shown) to increase the internal volume.

The first axial end 150 of the compressible hollow body 135 may be sealed, whereas the second axial end 155 may closed by a cap 160.

The first portion 140 of the compressible hollow body 135 may be the section of the sleeve-shaped body including the first axial end 150, whereas the second portion 145 may be the section of the sleeve-shaped body including the second axial end 155.

The first portion 140 of the sleeve-shaped body defining the compressible hollow body 135 may lie parallel on, and in thermal contact with, the flat surface 110 of the heat absorbing body 105.

For example, the first axial end 150 may be located in proximity of the center of the heat absorbing body 105 and the first portion 140 may extend radially towards the perimetral edge thereof.

The second portion 145 of the sleeve-shaped body defining the compressible hollow body 135 may project axially outside of the perimetral edge of the heat absorbing body 105 and may be in thermal contact with the heat releasing body 120 through the second axial end 155.

More particularly, the cap 160 closing the second axial end 155 of the compressible hollow body 135 may be coupled to the heat releasing body 120 to exchange heat therewith.

In order to improve the heat exchange, this coupling may be achieved through metal straw and/or protrusions (not shown) that increase the mutual contact area.

According to the example illustrated in the figures, the first portions 140 of the compressible hollow bodies 135 are globally arranged in a radial pattern around the center of the heat absorbing body 105, preferably angularly equidistant from one another.

However, it is not excluded that, in other embodiments, the compressible hollow bodies 135 may be shaped and/or arranged differently and, in general, in such a way as to form a pattern as ramified as possible.

Irrespective of that, it is preferable that the compressible hollow bodies 135 are joint together to form a single pad, for example a single pad that rests in thermal contact with the flat surface 110 of the heat absorbing body 105.

This pad and/or the individual compressible hollow bodies 135 may be made of a flexible polymeric material, in order to be squeezable when pressed.

Even if the heat transferring system 130 according to this example includes a plurality of compressible hollow bodies 135, other embodiments of the invention could involve the use of a single compressible hollow body, for example of a different shape and/or dimensions.

The important thing is that an excellent thermal coupling exists between the heat absorbing body 105 and the first portion or portions 140 of the compressible hollow body or bodies 135.

Each compressible hollow body 135 is filled up with a gas, for example air and/or freon.

In general, it is preferable that the thermal transmittance of this gas is as high as possible.

The heat transferring system 130 of the cooling device 100 further comprises at least one thrusting body or movable body 165, which may be located on the side of the heat absorbing body 105 that is in thermal contact with the compressible hollow bodies 135, for example in front of the flat surface 110.

This thrusting body 165 may be rigid and/or may be made of a thermal insulating material.

The thrusting body 165 is movable to alternatingly squeeze and release the first portion 140 of one or more of the compressible hollow bodies 135.

In other words, the thrusting body 165 may be movable between a first position, in which the thrusting body 165 squeezes the first portion 140 of the compressible hollow body 135, and at least one second position, in which the thrusting body 165 releases said squeeze.

In particular, the thrusting body 165 may squeeze the first portion 140 of the compressible hollow body 135 against the heat absorbing body 105, for example against the flat surface 110 thereof.

This way, when the first portion 140 of the compressible hollow body 135 is squeezed, the gas contained therein is pumped into the second portion 145 of the compressible hollow body 135.

When the squeeze is released, the pressurized gas contained in the second portion 145 is free to flow and to inflate the first portion 140 of the compressible hollow body 135 again.

The movement of the thrusting body 165 may be actuated by an electric motor 170, for example a stepper motor.

In the present embodiment, the thrusting body 165 is embodied as an elongated body, which extends predominantly along a longitudinal axis lying parallel to the flat surface 110 of the heat absorbing body 105.

For example, the thrusting body 165 may be embodied as a cylindrical roller configured to be able to rotate on itself around an axis of rotation that coincides with the foresaid longitudinal axis.

The thrusting body 165 may be located in contact with the flat surface 110 of the heat absorbing body 105, or at least at a distance therefrom that is smaller than the thickness of the first portion 140 of compressible hollow bodies 135 when inflated, and the electric motor 170 may be configured to make the thrusting body 165 move along a direction that is parallel to the flat surface 110 of the heat absorbing body 105 and transversal to the longitudinal axis of the thrusting body 165.

This way, the thrusting body 165 “sweeps” or “roll-on” the flat surface 110 of the heat absorbing body 105 and is thus able to squeezes the first portion 140 of one or more of the compressible hollow bodies 135.

Preferably, the thrusting body 165 is configured and moved to squeeze the first portions 140 of all the compressible hollow bodies 135 one after the other.

To achieve this effect, the thrusting body 165 may be arranged radially with respect to the center of the flat surface 110 of the heat absorbing body 105, and the electric motor 170 may be configured to revolve the thrusting body 165 around an axis of revolution containing the center of the radial pattern formed by the first portions 140 of the compressible hollow bodies 135 and perpendicular to the flat surface 110 of the heat absorbing body 105.

In order to increase the frequency with which the first portion 140 of each compressible hollow body 135 is squeezed and released, the heat transferring system 130 may preferably comprise a plurality of the thrusting bodies 165 described above, all of which may be actuated by the single electric motor 170.

In particular, the heat transferring system 130 may comprise a sort of impeller comprising a central hub 175 centered on the axis of revolution and a plurality of thrusting bodies 165 arranged in a radial pattern (preferably angularly equidistant to one another) around the central hub 175.

The electric motor 170 may thus be simply configured to rotate the central hub 175 of the impeller around the axis of revolution.

While this embodiment involves a revolutionary movement of the thrusting bodies 165, it is not excluded that, in other embodiments, the thrusting bodies 165 are moved back and forth in a linear direction.

It is not even excluded that, in some other embodiments, the thrusting body or bodies 165 may have different shape and/or that each of them is moved towards and away from the first portion or portions 140 of the compressible hollow body or bodies 135 in a direction perpendicular to the flat surface 110 of the heat absorbing body 105.

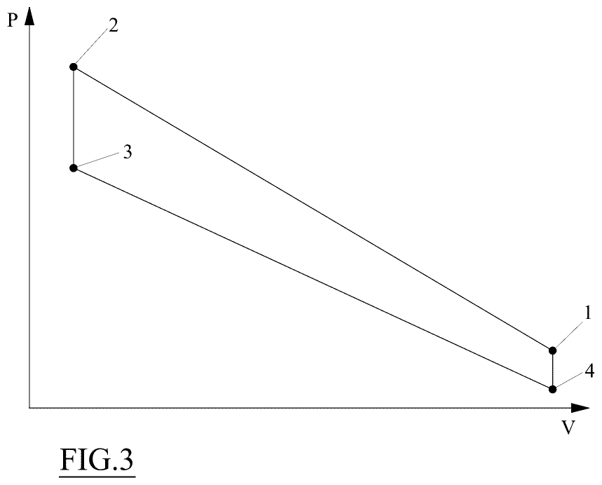

The thermodynamic cycle performed by the cooling device 100 is now illustrated with reference to the diagram of FIG. 3.

As anticipated, when a thrusting body 165 squeezes the first portion 140 of a compressible hollow body 135, all the gas contained therein is forced to move in the second portion 145 of the compressible hollow body 135.

This causes an adiabatic compression of the gas (from point 1 to point 2 of the diagram) so that its pressure and temperature raise.

In particular, the temperature of the gas at the end of the adiabatic compression may be higher than the temperature of the heat releasing body 120.

As a consequence, in a second phase (from point 2 to point 3 of the diagram), while the thrusting body 165 still keeps the first portion 140 of the compressible hollow body 135 squeezed, the hot gas heats the heat releasing body 120 that in turn releases at least part of this heat to the environment.

At the same time, the gas temperature decreases through an isochoric process.

When the gas temperature is equal or almost equal to the temperature of the heat releasing body 120, the thrusting body 165 releases the squeeze, so that the compressed gas is free to flow and to inflate the entire compressible hollow body 135, thereby undergoing to an adiabatic expansion (from point 3 to point 4 of the diagram).

During this adiabatic expansion, the gas temperature decreases below the temperature of the heat absorbing body 105.

Therefore, during a fourth phase (from point 3 to point 4 of the diagram), while the compressible hollow body 135 is still completely inflated, the cold gas cools the heat absorbing body 105 that in turn draws heat from the space or the object to be cooled.

At the same time, the gas temperature increases through an isochoric process.

When the gas temperature is equal or almost equal to the temperature of the heat absorbing body 105, the thrusting body 165, or another thrusting body 165, may squeeze the first portion 140 of the compressible hollow body 135 again, and the thermodynamic cycle is repeated.

This thermodynamic cycle is performed and repeated for each and any compressible hollow body 135, thereby increasing the energy efficiency.

Thanks to this thermodynamic cycle, the cooling device 100 is thus globally able to transfer heat from the heat absorbing body 105 (cold side) to the heat releasing body (hot side).

As a consequence, the cooling device 100 may be advantageously used to cool any space or object that needs to be refrigerated, simply by placing the heat absorbing body 105 in thermal relation with that space or object and exposing the heat releasing body 120 to the external environment.

Therefore, the cooling device 100 may be incorporated in any other electronic appliance having thermal sensitive components, for example but not exclusively in an inductive wireless charger.

The cooling device 100 is particularly advantageous because it can be manufactured at low cost, can be easily miniaturized, can be quite silent in operation and can also achieve high level of energy efficiency.

### NOTE

It is to be understood that the above-referenced arrangements are only illustrative of the application for the principles of the present invention. Numerous modifications and alternative arrangements can be devised without departing from the spirit and scope of the present invention. While the present invention has been shown in the drawings and fully described above with particularity and detail in connection with what is presently deemed to be the most practical and preferred example(s) of the invention, it will be apparent to those of ordinary skill in the art that numerous modifications can be made without departing from the principles and concepts of the invention as set forth herein.

1. A cooling device comprising:
a heat absorbing body,
a heat releasing body, and
a heat transferring system configured to transfer heat from the heat absorbing body to the heat releasing body,
wherein the heat transferring system comprises at least:
a deformable body,
a gas within the deformable body,
a movable body capable of alternatingly squeezing and releasing a portion of the deformable body, and
an electric motor configured to actuate the movable body.

2. A cooling device according to claim 1, wherein the deformable body has a first portion in thermal contact with the heat absorbing body and a second portion in thermal contact with the heat releasing body.

3. A cooling device according to claim 2, wherein the heat absorbing body has at least one flat surface and the first portion of the deformable body is in thermal contact with said flat surface.

4. A cooling device according to claim 1, wherein the deformable body is a sleeve-shaped body.

5. A cooling device according to claim 4, wherein the second portion of the deformable body includes an axial end of the sleeve-shaped body that is in thermal contact with the heat releasing body.

6. A cooling device according to claim 5, wherein the axial end of the sleeve-shaped body is closed by a cap that is coupled to the heat releasing body to exchange heat therewith.

7. A cooling device according to claim 6, wherein the cap is coupled to the heat releasing body through metal straw and/or protrusions.

8. A cooling device according to claim 3, wherein the first portion of the deformable body lies parallel on, and in thermal contact with, the flat face of the heat absorbing body.

9. A cooling device according to claim 1, wherein the heat transferring system comprises a plurality of deformable bodies.

10. A cooling device according to claim 9, wherein the first portions of the deformable bodies are arranged in a radial pattern around a center.

11. A cooling device according to claim 9, wherein the deformable bodies are joint together to form a single pad.

12. A cooling device according to claim 9, wherein the movable body is movable across the first portions of all the deformable bodies, in order to squeeze them one after the other.

13. A cooling device according to claim 10, wherein the electric motor is configured to revolve the movable body around an axis of revolution (Z) containing the center of the radial pattern.

14. A cooling device according to claim 1, wherein the movable body is a roller rolling across a portion of the deformable body.

15. A cooling device according to claim 14, wherein the roller is configured to rotate on itself around an axis of rotation parallel to the flat surface of the heat absorbing body.

16. A cooling device according to claim 1, wherein the heat transferring system comprises a plurality of movable bodies.

17. A cooling device according to claim 16, wherein the electric motor is configured to move all the movable bodies.

18. A cooling device according to claim 1, wherein the electric motor is a stepper motor.

19. A cooling device according to claim 1, wherein the heat releasing body is a flat body.

20. A cooling device according to claim 1, wherein the heat releasing body is ring-shaped.

21. A cooling device according to claim 1, wherein the heat releasing body comprises thermal dissipative fins.

22. A cooling device according to claim 1, wherein the deformable body is made of polymeric material.

23. A cooling device according to claim 1, wherein the gas has high thermal transmittance.
